(19) United States
(12) Patent Application Publication
(10) Pub. No.: US 2026/0262450 A1
(43) Pub. Date: Sep. 3, 2026

(54) MAGNETIC MEMORY UNIT AND MAGNETIC MEMORY

(71) Applicant: SUZHOU INSTON TECHNOLOGY CO., LTD., Suzhou (CN)

(72) Inventors: Zheng ZHU, Suzhou (CN); Shangkun LI, Suzhou (CN); Albert LEE, Suzhou (CN); Di WU, Suzhou (CN)

(21) Appl. No.: 19/147,278

(22) PCT Filed: Jan. 8, 2024
(86) PCT No.: PCT/CN2024/071237

§ 371 Date: Jul. 10, 2025

(30) Foreign Application Priority Data
Jan. 12, 2023 (CN) 202310038994.5

(51) Int. Cl. H10N 50/85; G11C 11/16; H10N 50/10

(52) U.S. Cl. CPC H10N 50/85; H10N 50/10; G11C 11/161

(57) ABSTRACT

The present disclosure discloses a magnetic memory unit and a magnetic memory. The magnetic memory unit includes an upper electrode, a pinning layer, a coupling layer, a fixed magnetic layer, a tunneling barrier layer, a free magnetic layer, and a lower electrode which are sequentially stacked, the coupling layer is configured to form an anti-ferromagnetic coupling between the fixed magnetic layer and the pinning layer, the pinning layer is configured to eliminate a stray field applied on the free magnetic layer by the fixed magnetic layer, and material-doped regions are arranged in the pinning layer. The arrangement of the pinning layer can eliminate the stray field of the fixed magnetic layer on the free magnetic layer, and the material-doped regions arranged in the pinning layer can ensure that the stray field experienced by the free magnetic layer remains at a very small value under temperature changes.

### TECHNICAL FIELD

The present disclosure relates to the technical field of magnetic storage, and in particular to a magnetic memory unit and a magnetic memory.

### BACKGROUND

The magnetic random access memory (MRAM) is considered as the future solid-state nonvolatile memory, featuring high-speed reading and writing, large capacity, low energy consumption, etc. The magnetic random access memory generates a stray field, which will adversely affect the magnetic random access memory. In the related art, the stray field is reduced by adding multiple artificial anti-ferromagnetic layers. However, temperature has a great influence on the stray field, and the related art cannot eliminate the temperature-dependent stray field in the MRAM, and cannot ensure that the stray field remains at a very small value under temperature changes.

### SUMMARY

In view of the above, it is necessary to provide a magnetic memory unit and a magnetic memory, which can solve the technical problem in the related art, where the temperature-dependent stray field in the MRAM cannot be eliminated, and the stray field cannot remain at a very small value under temperature changes.

The magnetic memory unit provided by the present disclosure includes an upper electrode, a pinning layer, a coupling layer, a fixed magnetic layer, a tunneling barrier layer, a free magnetic layer, and a lower electrode which are sequentially stacked, where the coupling layer is configured to form an anti-ferromagnetic coupling between the fixed magnetic layer and the pinning layer, the pinning layer is configured to eliminate a stray field of the fixed magnetic layer on the free magnetic layer, and material-doped regions are arranged in the pinning layer.

Further, a plurality of material-doped regions are arranged and evenly distributed in the pinning layer.

Further, the material-doped region is an alloy material.

Further, the material of the material-doped region includes one or more of vanadium, chromium, copper, niobium, molybdenum, ruthenium, rhodium, tantalum, tungsten, rhenium, iridium, niobium, zirconium, yttrium, iron, nickel, cobalt, boron, carbon, nitrogen, oxygen, neodymium, europium, gadolinium, terbium, dysprosium, holmium, manganese, aluminum, silicon, phosphorus, gallium, germanium, arsenic, indium, tin, and antimony.

Further, the material of the pinning layer includes a ferromagnetic material, an anti-ferromagnetic material, or a ferrimagnetic materials

Further, the material of the fixed magnetic layer includes a ferromagnetic material, an anti-ferromagnetic material, or a ferrimagnetic material.

Further, the material of the free magnetic layer includes a ferromagnetic material, an anti-ferromagnetic material, or a ferrimagnetic material.

Further, the material of the tunneling barrier layer is a metal oxide.

Further, the material of the coupling layer includes one or more of vanadium, chromium, copper, niobium, molybdenum, ruthenium, rhodium, tantalum, tungsten, rhenium, and iridium.

The present disclosure further provides a magnetic memory, including the aforementioned magnetic memory unit.

According to the magnetic memory unit and the magnetic memory provided by the present disclosure, the magnetic memory unit includes the upper electrode, the pinning layer, the coupling layer, the fixed magnetic layer, the tunneling barrier layer, the free magnetic layer and the lower electrode which are sequentially stacked. The arrangement of the pinning layer can eliminate the stray field of the fixed magnetic layer on the free magnetic layer, and the material-doped regions arranged in the pinning layer can ensure that the stray field experienced by the free magnetic layer remains at a very small value under temperature changes. The intensity of the stray field is directly proportional to saturation magnetization of the fixed magnetic layer and the pinning layer. However, due to differences in the structural materials of the fixed magnetic layer and the pinning layer, the saturation magnetization does not synchronously change with temperature, as shown in FIG. 3(a). This leads to a variation in the stray field as temperature changes, and the larger the temperature change, the greater the deviation of the stray field, as indicated by the dotted line in FIG. 4. By arranging the material-doped regions in the pinning layer, the trend of the saturation magnetization of the pinning layer with the temperature changes can be altered. By accurately controlling the amount of the predetermined material-doped regions, the saturation magnetization of the fixed magnetic layer and the pinning layer can be made to consistently change with temperature, as shown in FIG. 3(b). Ultimately, this allows the stray field to remain at a very small value (approximately equal to 0) and not change with temperature, as indicated by the solid line in FIG. 4.

### BRIEF DESCRIPTION OF THE DRAWINGS

In order to more clearly illustrate the technical solution in embodiments of the present disclosure or the prior art, the accompanying drawings required to be used in the description of the embodiments or the prior art will be introduced briefly below. Apparently, the accompanying drawings described below are merely some embodiments of the present disclosure, and those of ordinary skill in the art can also obtain other accompanying drawings according to the structures shown in these drawings without making creative efforts.

FIG. 1 is a schematic structural diagram of a magnetic memory unit according to an embodiment of the present disclosure.

FIG. 2 is a schematic structural diagram of a pinning layer provided with material-doped regions according to an embodiment of the present disclosure.

FIG. 3(a) is a relationship graph between saturation magnetization of the pinning layer and a fixed magnetic layer and temperature, where the pinning layer is not provided with material-doped regions, according to an embodiment of the present disclosure; and FIG. 3(b) is a relationship graph between the saturation magnetization of the pinning layer and the fixed magnetic layer and temperature, where the pinning layer is provided with material-doped regions, according to an embodiment of the present disclosure.

FIG. 4 is a relationship graph between a stray field experienced by a free magnetic layer and temperature before and after the pinning layer is provided with the material-doped regions according to an embodiment of the present disclosure.

FIG. 5 is a comparison graph showing changes in saturation magnetization of CoPt alloy with temperature under different amounts of doped tungsten according to an embodiment of the present disclosure.

FIG. 6 is a schematic structural diagram of a magnetic memory unit with an in-plane magnetized pinning layer according to an embodiment of the present disclosure.

### REFERENCE NUMERALS

100. Upper electrode; 200. Pinning layer; 210. Material-doped region; 300. Coupling layer; 400. Fixed magnetic layer; 500. Tunneling barrier layer; 600. Free magnetic layer; 700. Lower electrode.

The implementation, functional characteristics and advantages of the objective of the present disclosure will be further illustrated with reference to embodiments and the accompanying drawings.

### DETAILED DESCRIPTION OF THE EMBODIMENTS

The technical solution according to an embodiment of the present disclosure will be clearly and fully described below with reference to the drawings in the embodiment of the present disclosure, and it is obvious that the described embodiments are merely part of embodiments of the present disclosure rather than all of them. On the basis of the embodiments in the present disclosure, all other embodiments which those skilled in the art obtain without making creative efforts shall fall within the protection scope of the present disclosure.

It should be noted that all directional indications (such as upper, lower, left, right, front and back) in the embodiments of the present disclosure are only used to explain the relative positional relationships, movements and so on of various components in a certain posture (as shown in the accompanying drawings), and if the certain posture changes, the directional indications will also change accordingly.

In addition, descriptions involving “first,” “second” and so on in the present disclosure are only used for descriptive purposes and are not to be construed as indicating or implying their relative importance or implicitly indicating the number of technical features indicated. Therefore, features defined as “first” and “second” may explicitly or implicitly include at least one of these features. In addition, “and/or” in the whole specification includes three solutions, for example, A and/or B includes a technical solution A, a technical solution B, and a technical solution where both A and B are satisfied. In addition, the technical solutions of various embodiments may be combined with one another, as long as the combinations can be implemented by those of ordinary skill in the art. If combinations of the technical solutions are contradictory or cannot be implemented, it should be considered that such combinations of the technical solutions do not exist, and do not fall within the protection scope claimed by the present disclosure as well.

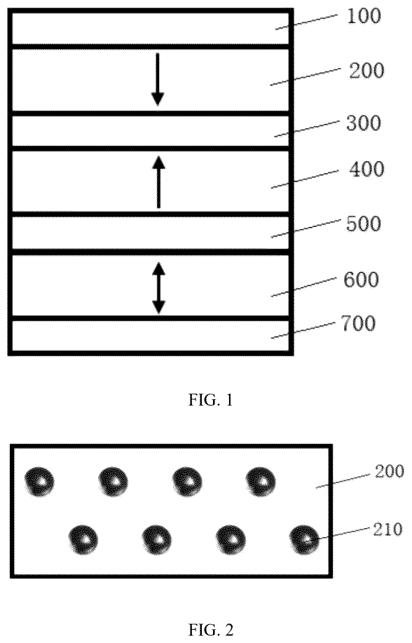

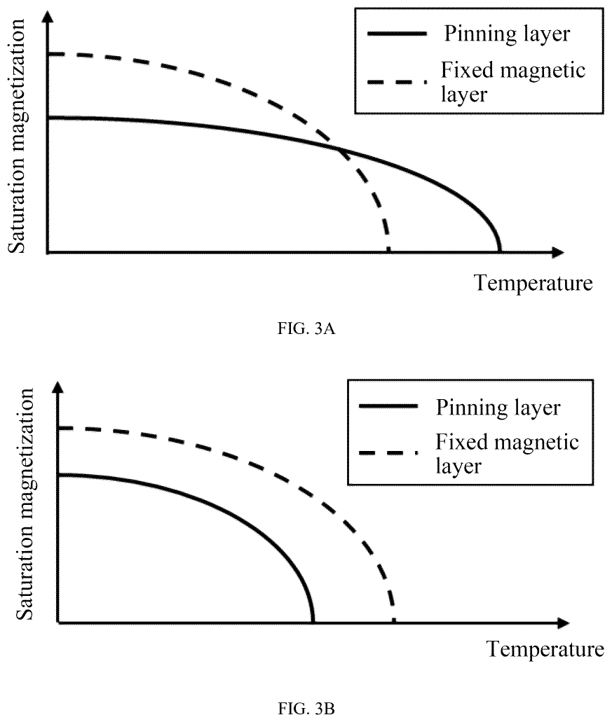

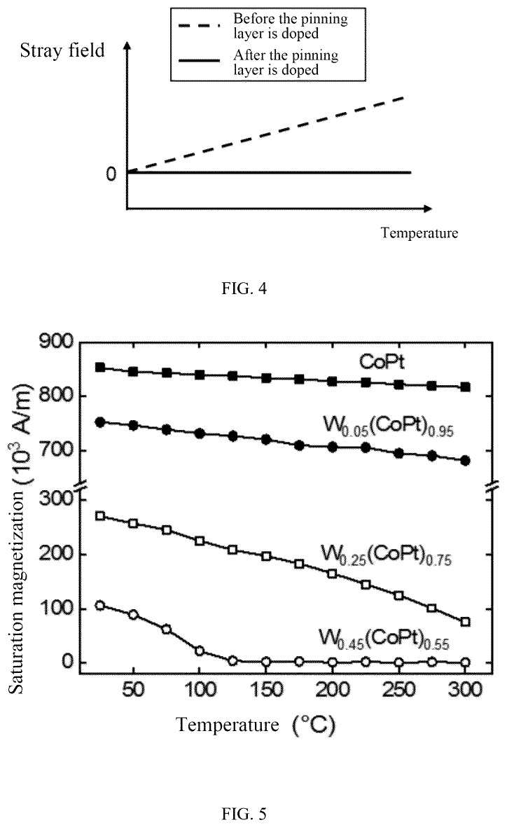

As shown in FIG. 1, in some embodiments, a magnetic memory unit includes an upper electrode 100, a pinning layer 200, a coupling layer 300, a fixed magnetic layer 400, a tunneling barrier layer 500, a free magnetic layer 600, and a lower electrode 700 which are sequentially stacked, where the coupling layer 300 is configured to form an anti-ferromagnetic coupling between the fixed magnetic layer 400 and the pinning layer 200, the pinning layer 200 is configured to eliminate a stray field of the fixed magnetic layer 400 on the free magnetic layer 600, and material-doped regions are arranged in the pinning layer 200 (meaning that other elements are doped in the pinning layer 200). The arrangement of the pinning layer 200 can eliminate the stray field of the fixed magnetic layer 400 on the free magnetic layer 600, and the material-doped regions arranged in the pinning layer 200 can ensure that the stray field experienced by the free magnetic layer 600 remain at a very small value under temperature changes, thereby achieving an effect of full-temperature stray field compensation. The intensity of the stray field is directly proportional to the saturation magnetization of the fixed magnetic layer 400 and the pinning layer 200. However, due to differences in the structural materials of the fixed magnetic layer 400 and the pinning layer 200, the saturation magnetization does not synchronously change with temperature, as shown in FIG. 3(a). This leads to a variation in the stray field as temperature changes, and the larger the temperature change, the greater the compensation for the stray field, as indicated by the dotted line in FIG. 4. By arranging the material-doped regions in the pinning layer 200, the trend of the saturation magnetization of the pinning layer 200 with the temperature changes can be altered. By accurately controlling the amount of the predetermined material-doped regions, the saturation magnetization of the fixed magnetic layer 400 and the pinning layer 200 can be made to consistently change with temperature, as shown in FIG. 3(b). Ultimately, this allows the stray field to remain at a very small value (approximately equal to 0) and not change with temperature, as indicated by the solid line in FIG. 4.

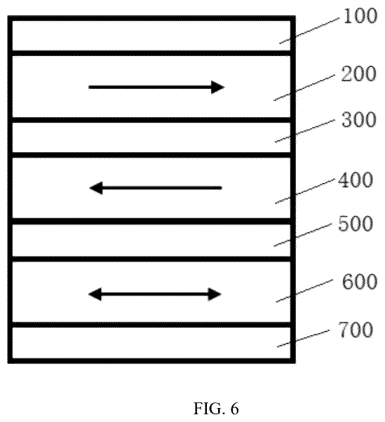

The pinning layer 200 may be either in-plane magnetized (as shown in FIG. 6) or out-of-plane magnetized. The pinning layer 200 is arranged between the upper electrode 100 and the coupling layer 300. The coupling layer 300 is formed on a side, distal from the upper electrode 100, of the pinning layer 200 (i.e., under the pinning layer 200 in FIG. 1). The fixed magnetic layer is formed on a side, distal from the pinning layer 200, of the coupling layer 300 (i.e., under the coupling layer 300 in FIG. 1), and may be either in-plane magnetized or out-of-plane magnetized. The tunneling barrier layer 500 is formed on a side, distal from the coupling layer 300, of the fixed magnetic layer 400 (i.e., under the fixed magnetic layer 400 in FIG. 1). The free magnetic layer 600 is formed on a side, distal from the fixed magnetic layer 400, of the tunneling barrier layer 500 (i.e., under the fixed magnetic layer 400 in FIG. 1). A magnetic moment direction of the free magnetic layer 600 serves as an information carrier, and the free magnetic layer 600 may be either in-plane magnetized or out-of-plane magnetized.

Specifically, as shown in FIG. 2, a plurality of material-doped regions are arranged and evenly distributed in the pinning layer 200, which can more efficiently eliminate the temperature dependence of the stray field.

More specifically, the material-doped region is an alloy material or an intercalated material.

Further, the material-doped region may be transition metal elements such as vanadium (V), chromium (Cr), copper (Cu), niobium (Nb), molybdenum (Mo), ruthenium (Ru), rhodium (Rh), tantalum (Ta), tungsten (W), rhenium (Re), iridium (Ir), niobium (Nb), zirconium (Zr), yttrium (Y), iron (Fe), nickel (Ni) and cobalt (Co), or light elements such as boron (B), carbon (C), nitrogen (N) and oxygen (O), or rare earth elements such as neodymium (Nd), europium (Eu), gadolinium (Gd), terbium (Tb), dysprosium (Dy) and holmium (Ho), or elements such as manganese (Mn), aluminum (Al), silicon (Si), phosphorus (P), gallium (Ga), germanium (Ge), arsenic (As), indium (In), tin (Sn) and antimony (Sb).

In the present embodiment, the material of the pinning layer 200 includes a ferromagnetic material, an anti-ferromagnetic material, or a ferrimagnetic material. The material of the fixed magnetic layer 400 includes a ferromagnetic material, an anti-ferromagnetic material, or a ferrimagnetic material. The material of the free magnetic layer 600 includes a ferromagnetic material, an anti-ferromagnetic material, or a ferrimagnetic material.

Specifically, the magnetic material may be any existing alloy material or multilayer film structure composed of one or more of iron (Fe), nickel (Ni) and cobalt (Co). In addition, the magnetic material may include transition metal elements such as niobium (Nb), zirconium (Zr) and yttrium (Y), or light elements such as boron (B), carbon (C), nitrogen (N) and oxygen (O), or rare earth elements such as neodymium (Nd), europium (Eu), gadolinium (Gd), terbium (Tb), dysprosium (Dy) and holmium (Ho), and any existing Heusler alloy or other alloys formed by manganese (Mn), aluminum (Al), silicon (Si), phosphorus (P), gallium (Ga), germanium (Ge), arsenic (As), indium (In), tin (Sn), antimony (Sb), etc.

Further, the tunneling barrier layer 500 is an insulating layer.

Further, the material of the tunneling barrier layer 500 is a metal oxide. Materials, such as aluminum oxide (AlOx), magnesium oxide (MgO), silicon oxide (SiOx), hafnium oxide (HfOx) and magnesium aluminum oxide (MgAlO), may be adopted as the metal oxide.

Specifically, the material of the coupling layer 300 includes a combination of one or more of vanadium, chromium, copper, niobium, molybdenum, ruthenium, rhodium, tantalum, tungsten, rhenium, and iridium.

In another embodiment, a magnetic memory includes the magnetic memory unit.

FIG. 3(a) is a relationship graph between saturation magnetization of the pinning layer and the fixed magnetic layer and temperature, where the pinning layer is not provided with material-doped regions, according to an embodiment of the present disclosure; and FIG. 3(b) is a relationship graph between the saturation magnetization of the pinning layer and the fixed magnetic layer and temperature, where the pinning layer is provided with the material-doped regions, according to an embodiment of the present disclosure.

FIG. 4 is a relationship graph between the stray field experienced by the free magnetic layer and temperature before and after the pinning layer is provided with the material-doped regions according to an embodiment of the present disclosure.

FIG. 5 is a comparison graph showing changes in saturation magnetization of CoPt alloy with temperature under different amounts of doped tungsten. The higher the content of W, the more dramatically the saturation magnetization of CoPt alloy changes with temperature, proving that the change trend of saturation magnetization with temperature can be altered by doping, thereby eliminating the variation of the stray field with temperature.

The above descriptions are merely preferred embodiments of the present disclosure, and should not be construed as limiting the patent scope of the present disclosure. Any equivalent structural transformations made by using the contents of the specification and accompanying drawings of the present disclosure or direct/indirect applications in other related technical fields under the inventive concept of the present disclosure shall fall within the patent protection scope of the present disclosure.

1. A magnetic memory unit, comprising an upper electrode, a pinning layer, a coupling layer, a fixed magnetic layer, a tunneling barrier layer, a free magnetic layer, and a lower electrode which are sequentially stacked, wherein the coupling layer is configured to form an anti-ferromagnetic coupling between the fixed magnetic layer and the pinning layer, the pinning layer is configured to eliminate a stray field of the fixed magnetic layer on the free magnetic layer, and material-doped regions are arranged in the pinning layer.

2. The magnetic memory unit according to claim 1, wherein a plurality of material-doped regions are arranged and evenly distributed in the pinning layer.

3. The magnetic memory unit according to claim 1, wherein the material-doped region is an alloy material.

4. The magnetic memory unit according to claim 1, wherein the material of the material-doped region comprises one or more of vanadium, chromium, copper, niobium, molybdenum, ruthenium, rhodium, tantalum, tungsten, rhenium, iridium, niobium, zirconium, yttrium, iron, nickel, cobalt, boron, carbon, nitrogen, oxygen, neodymium, europium, gadolinium, terbium, dysprosium, holmium, manganese, aluminum, silicon, phosphorus, gallium, germanium, arsenic, indium, tin, and antimony.

5. The magnetic memory unit according to claim 1, wherein the material of the pinning layer comprises a ferromagnetic material, an anti-ferromagnetic material, or a ferrimagnetic material.

6. The magnetic memory unit according to claim 1, wherein the material of the fixed magnetic layer comprises a ferromagnetic material, an anti-ferromagnetic material, or a ferrimagnetic material.

7. The magnetic memory unit according to claim 1, wherein the material of the free magnetic layer comprises a ferromagnetic material, an anti-ferromagnetic material, or a ferrimagnetic material.

8. The magnetic memory unit according to claim 1, wherein the material of the tunneling barrier layer is a metal oxide.

9. The magnetic memory unit according to claim 1, wherein the material of the coupling layer comprises one or more of vanadium, chromium, copper, niobium, molybdenum, ruthenium, rhodium, tantalum, tungsten, rhenium, and iridium.

10. (canceled)
